(19) United States
(12) Patent Application Publication
(10) Pub. No.: US 2024/0381543 A1
(43) Pub. Date: Nov. 14, 2024

(54) ELECTRONIC DEVICE

(71) Applicant: Murata Manufacturing Co., Ltd., Nagaokakyo-shi (JP)

(72) Inventors: Hiroaki KITADA, Nagaokakyo-shi (JP); Hidekazu KANO, Nagaokakyo-shi (JP)

(21) Appl. No.: 18/782,663

(22) Filed: Jul. 24, 2024

Related U.S. Application Data
(63) Continuation of application No. PCT/JP2023/004156, filed on Feb. 8, 2023.

(30) Foreign Application Priority Data
Feb. 10, 2022 (JP) 2022-019249

(51) Int. Cl. H05K 5/00; H05K 5/02

(52) U.S. Cl. CPC H05K 5/0018; H05K 5/0217

(57) ABSTRACT

An electronic device that includes: an operation panel having a first upper main surface and a first lower main surface that are arranged in a vertical direction such that a part of a body of a user or an operation member is capable of contacting the first upper main surface; a sensor fixed to the first lower main surface and constructed to detect deformation of the operation panel; and an adhesive member fixing the sensor to the first lower main surface. The adhesive member has a Young's modulus of 0.9 MPa to 10 MPa.

### CROSS REFERENCE TO RELATED APPLICATIONS

The present application is a continuation of International application No. PCT/JP2023/004156, filed Feb. 8, 2023, which claims priority to Japanese Patent Application No. 2022-019249, filed Feb. 10, 2022, the entire contents of each of which are incorporated herein by reference.

### TECHNICAL FIELD

The present disclosure relates to an electronic device including an operation panel.

### BACKGROUND ART

As an disclosure related to a conventional electronic device, for example, a pressing sensor described in Patent Document 1 is known. The pressing sensor includes an operation surface, a plate-shaped member, and a piezoelectric film. A user performs a pressing operation by touching the operation surface. The plate-shaped member becomes bent by the pressing operation. The piezoelectric film is bonded to the plate-shaped member to be bent together with the plate-shaped member. As a result, a pressing force is detected by the output of the piezoelectric film.
Patent Document 1: WO 2015/083678

### SUMMARY OF THE DISCLOSURE

By the way, there is a demand for accurately detecting, by the pressing sensor described in Patent Document 1, the magnitude of a force with which the user presses the operation surface.

Therefore, an object of the present disclosure is to provide an electronic device capable of accurately detecting the magnitude of a force with which a user presses an operation panel.

An electronic device according to an embodiment of the present disclosure includes: an operation panel having a first upper main surface and a first lower main surface that are arranged in a vertical direction such that a part of a body of a user or an operation member is capable of contacting the first upper main surface; a sensor fixed to the first lower main surface and constructed to detect deformation of the operation panel; and an adhesive member fixing the sensor to the first lower main surface, in which the adhesive member has a Young's modulus of 0.9 MPa to 10 MPa.

According to the electronic device according to the present disclosure, the magnitude of a force with which a user presses the operation panel can be accurately detected.

### BRIEF EXPLANATION OF THE DRAWINGS

FIG. 1 is an exploded perspective view of an electronic device 1.

FIG. 2 is a sectional view of an operation panel 2, a display panel 4, a buffer member 9, a plate-shaped member 7, an adhesive member 8, and a sensor 6 taken along line A-A.

FIG. 3 is a plan view of the sensor 6 as viewed in a downward direction and a sectional view of the sensor 6 as viewed in a forward direction.

FIG. 4 is a sectional view of the operation panel 2, the display panel 4, the buffer member 9, the plate-shaped member 7, the adhesive member 8, and the sensor 6.

FIG. 5 is a graph illustrating a relationship between an amount of stretching of the piezoelectric film 14 and time.

FIG. 6 is a graph illustrating a relationship between a Young's modulus of the adhesive member 8 and an overshoot rate.

### DESCRIPTION OF THE PREFERRED EMBODIMENTS

### Embodiments

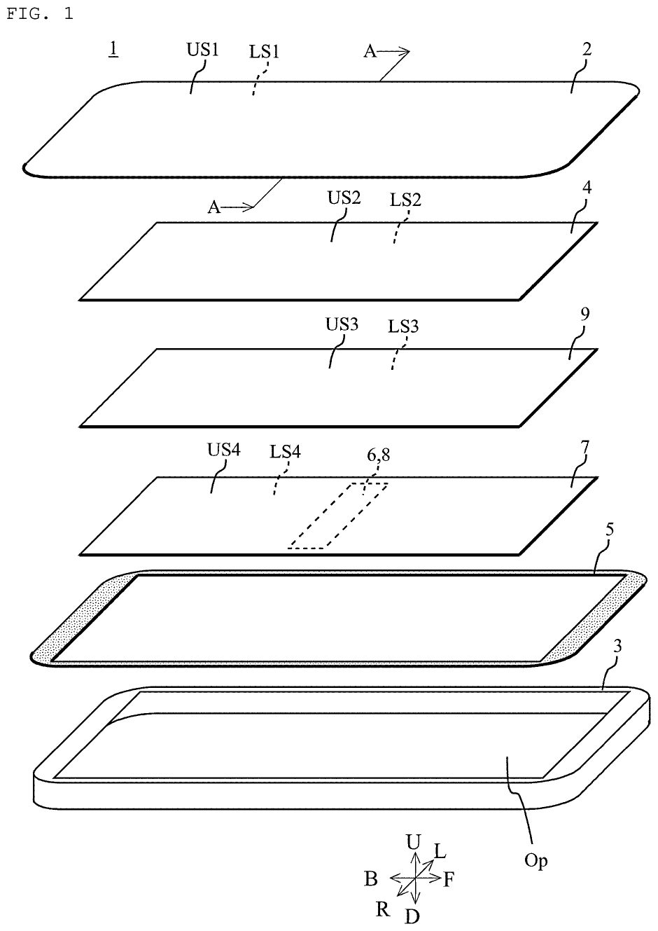

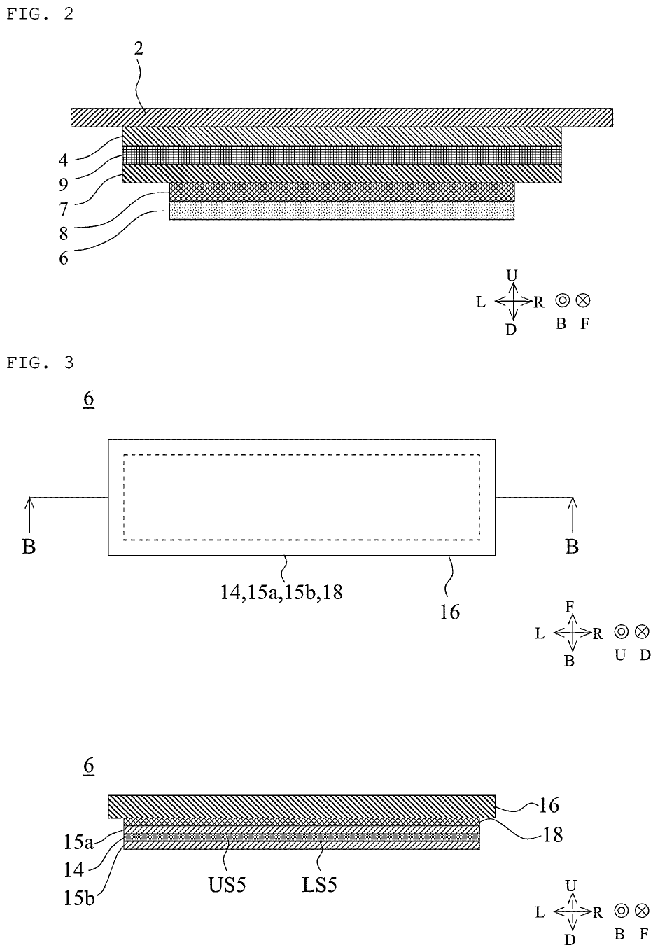

Hereinafter, a configuration of an electronic device 1 according to an embodiment of the present disclosure will be described with reference to the drawings. FIG. 1 is an exploded perspective view of the electronic device 1. FIG. 2 is a sectional view of an operation panel 2, a display panel 4, a buffer member 9, a plate-shaped member 7, an adhesive member 8, and a sensor 6 taken along line A-A. FIG. 3 is a plan view of the sensor 6 as viewed in a downward direction and a sectional view of the sensor 6 as viewed in a forward direction.

In the present specification, directions are defined as follows. In the electronic device 1, a direction in which a first upper main surface US1 and a first lower main surface LS1 of the operation panel 2 are arranged is defined as a vertical direction. As viewed in the vertical direction, a direction in which a long side of the operation panel 2 of the electronic device 1 extends is defined as a front-rear direction. As viewed in the vertical direction, a direction in which a short side of the operation panel 2 of the electronic device 1 extends is defined as a right-left direction. The vertical direction, the right-left direction, and the front-rear direction are orthogonal to each other. Note that the definition of directions in the present description is an example. Therefore, directions at the time of actual use of the electronic device 1 do not need to coincide with the directions in the present specification. Further, the vertical direction may be reversed in FIG. 1. The right-left direction may be reversed in FIG. 1. The front-rear direction may be reversed in FIG. 1.

The electronic device 1 is a portable electronic terminal such as a smartphone or a tablet computer. As illustrated in FIGS. 1 and 2, the electronic device 1 includes the operation panel 2, a housing 3, the display panel 4, an adhesive member 5, the sensor 6, the plate-shaped member 7, the adhesive member 8, and the buffer member 9.

As illustrated in FIG. 1, the operation panel 2 has the first upper main surface US1 and the first lower main surface LS1 that are arranged in the vertical direction. The operation panel 2 has a rectangular shape having two long sides extending in the front-rear direction and two short sides extending in the right-left direction as viewed in the vertical direction. A part of a body of a user or an operation member comes into contact with the first upper main surface US1 of the operation panel 2. In the present embodiment, the operation panel 2 is a transparent plate. The material of the operation panel 2 is, for example, glass.

As illustrated in FIG. 1, the display panel 4 has a second upper main surface US2 and a second lower main surface LS2 that are arranged in the vertical direction. The display panel 4 has a rectangular shape having two long sides extending in the front-rear direction and two short sides extending in the right-left direction as viewed in the vertical direction. The display panel 4 is fixed to the first lower main surface LS1 of the operation panel 2. The display panel 4 is fixed to the operation panel 2 with an adhesive, a double-sided tape, or the like. The entire display panel 4 overlaps the operation panel 2 as viewed in the vertical direction. The display panel 4 does not protrude from the outer edge of the operation panel 2 as viewed in the vertical direction. The display panel 4 is, for example, an organic EL display or a liquid crystal display. The display panel 4 may include a touch panel for detecting a position where the user touches the operation panel 2. However, the touch panel may be included in the operation panel 2.

As illustrated in FIG. 1, the buffer member 9 has a third upper main surface US3 and a third lower main surface LS3 that are arranged in the vertical direction. The buffer member 9 has a rectangular shape having two long sides extending in the front-rear direction and two short sides extending in the right-left direction as viewed in the vertical direction. The buffer member 9 is fixed to the first lower main surface LS1 of the operation panel 2. In the present specification, “the buffer member 9 is fixed to the first lower main surface LS1 of the operation panel 2” means that the buffer member 9 may be directly fixed to the first lower main surface LS1 of the operation panel 2, or the buffer member 9 may be fixed to another member fixed to the first lower main surface LS1 of the operation panel 2. In the present embodiment, the buffer member 9 is fixed to the second lower main surface LS2 of the display panel 4. The buffer member 9 is fixed to the display panel 4 with an adhesive, a double-sided tape, or the like. The entire buffer member 9 overlaps the display panel 4 as viewed in the vertical direction. The buffer member 9 does not protrude from the outer edge of the display panel 4 as viewed in the vertical direction.

The buffer member 9 absorbs an impact applied to the portable electronic terminal. For example, when the portable electronic terminal falls and collides with a floor or the like, the operation panel 2 may be deformed, and the operation panel 2 may collide with a member stored below an opening Op of the housing 3. At this time, the buffer member 9 absorbs an impact generated when the operation panel 2 and the member stored below the opening Op of the housing 3 collide with each other. Thus, the buffer member 9 suppresses damage to the operation panel 2. The buffer member 9 is, for example, a cushion, a sponge, an impact-absorbing gel, a double-sided tape, or the like.

As illustrated in FIG. 1, the plate-shaped member 7 has a fourth upper main surface US4 and a fourth lower main surface LS4 that are arranged in the vertical direction. The plate-shaped member 7 has a rectangular shape having two long sides extending in the front-rear direction and two short sides extending in the right-left direction as viewed in the vertical direction. The plate-shaped member 7 is fixed to the first lower main surface LS1 of the operation panel 2. In the present specification, “the plate-shaped member 7 is fixed to the first lower main surface LS1 of the operation panel 2” means that the plate-shaped member 7 may be directly fixed to the first lower main surface LS1 of the operation panel 2, or the plate-shaped member 7 may be fixed to another member fixed to the first lower main surface LS1 of the operation panel 2. In the present embodiment, the plate-shaped member 7 is fixed to the third lower main surface LS3 of the buffer member 9. The plate-shaped member 7 is fixed to the buffer member 9 with an adhesive, a double-sided tape, or the like. The entire plate-shaped member 7 overlaps the buffer member 9 as viewed in the vertical direction. In addition, the plate-shaped member 7 does not protrude from the outer edge of the buffer member 9 as viewed in the vertical direction. The rigidity of the plate-shaped member 7 is higher than the rigidity of the sensor 6 described later. The material of the plate-shaped member 7 is, for example, metal such as stainless used steel (SUS). In the present embodiment, the material of the plate-shaped member 7 is SUS. However, the material of the plate-shaped member 7 may be a material other than metal. The material other than the metal is, for example, resin. The plate-shaped member 7 may have a Young's modulus of 1 GPa or more.

As illustrated in FIG. 1, the housing 3 is located below the operation panel 2. The housing 3 is a box. The housing 3 has a rectangular shape as viewed in the vertical direction. A long side of the housing 3 extends in the front-rear direction. A short side of the housing 3 extends in the right-left direction. The outer edge of the housing 3 viewed in the vertical direction coincides with the outer edge of the operation panel 2 viewed in the vertical direction. An upper face of the housing 3 is open. The opening Op of the housing 3 has a rectangular shape as viewed in the vertical direction. Members such as a battery and a circuit board are stored below the opening Op of the housing 3.

As illustrated in FIG. 1, the adhesive member 5 fixes a part of the first lower main surface LS1 of the operation panel 2 to the housing 3. More specifically, the adhesive member 5 fixes the periphery of the opening Op of the housing 3 to the vicinity of the outer edge of the operation panel 2. Therefore, the adhesive member 5 has a rectangular frame shape surrounding the display panel 4 as viewed in the vertical direction. Therefore, the adhesive member 5 does not overlap the display panel 4 as viewed in the vertical direction. The adhesive member 5 as described above has waterproofness.

The sensor 6 detects deformation of the operation panel 2. As illustrated in FIG. 1, the sensor 6 is fixed to the first lower main surface LS1 of the operation panel 2. In the present specification, “the sensor 6 is fixed to the first lower main surface LS1 of the operation panel 2” means that the sensor 6 may be directly fixed to the first lower main surface LS1 of the operation panel 2, or the sensor 6 may be fixed to another member fixed to the first lower main surface LS1 of the operation panel 2. In the present embodiment, as illustrated in FIG. 1, the sensor 6 is fixed to the fourth lower main surface LS4 of the plate-shaped member 7. The sensor 6 is fixed to the plate-shaped member 7 by the adhesive member 8 described later. The sensor 6 has a rectangular shape as viewed in the vertical direction. The sensor 6 has a longitudinal direction extending in the right-left direction. The sensor 6 is located at the center of the operation panel 2 in the front-rear direction as viewed in the vertical direction.

When the operation panel 2 becomes bent downward due to the pressing of the operation panel 2 by the user, the display panel 4 and the plate-shaped member 7 also become bent downward. Then, the sensor 6 becomes bent downward together with the plate-shaped member 7. As a result, the sensor 6 outputs a detection signal corresponding to the deformation that has occurred in the operation panel 2 when the user presses the operation panel 2. Hereinafter, details of the sensor 6 will be described with reference to FIG. 3.

As illustrated in FIG. 3, the sensor 6 includes a piezoelectric film 14, an upper electrode 15a, a lower electrode 15b, a substrate 16, and an adhesive layer 18. The piezoelectric film 14 has a sheet shape. Therefore, as illustrated in FIG. 3, the piezoelectric film 14 has a fifth upper main surface US5 and a fifth lower main surface LS5 that are arranged in the vertical direction. A length of the piezoelectric film 14 in the right-left direction is longer than a length of the piezoelectric film 14 in the front-rear direction. That is, the piezoelectric film 14 has a longitudinal direction extending in the right-left direction. In the present embodiment, the piezoelectric film 14 has a rectangular shape having a long side extending in the right-left direction as viewed in the vertical direction. The piezoelectric film 14 generates an electric charge according to an amount of deformation of the piezoelectric film 14. In the present embodiment, the electric charge generated by the piezoelectric film 14 is mainly due to stretching and contraction in the right-left direction. As a result, a length of the sensor 6 in the lateral direction may be 10 mm or less, and the ratio of a length of the sensor 6 in the longitudinal direction to the length of the sensor 6 in the lateral direction may be 3 to 10. In the present embodiment, the piezoelectric film 14 is a PLA film. The piezoelectric film 14 will be described below in more detail.

The piezoelectric film 14 has a characteristic in which the polarity of an electric charge generated when the piezoelectric film 14 is stretched in the right-left direction is opposite to the polarity of an electric charge generated when the piezoelectric film 14 is stretched in the front-rear direction. Specifically, the piezoelectric film 14 is a film formed of a chiral polymer. The chiral polymer is, for example, polylactic acid (PLA), particularly poly-L-lactic acid (PLLA). PLLA, which is a chiral polymer, has a main chain with a helical structure. PLLA has piezoelectricity in which molecules are oriented when the PLLA is uniaxially stretched. The piezoelectric film 14 has a piezoelectric constant of d14. The uniaxial stretching direction (orientation direction) of the piezoelectric film 14 forms an angle of 45 degrees with respect to each of the front-rear direction and the right-left direction. This angle of 45 degrees includes, for example, angles ranging from 45 degrees plus 10 degrees to 45 degrees minus 10 degrees. As a result, the piezoelectric film 14 generates an electric charge when the piezoelectric film 14 is stretched in the right-left direction or contracted in the right-left direction. The polarity of an electric charge generated by the piezoelectric film 14 when the piezoelectric film 14 is stretched in the right-left direction is different from the polarity of an electric charge generated by the piezoelectric film 14 when the piezoelectric film 14 is stretched in the front-rear direction. The piezoelectric film 14 generates a positive charge when the piezoelectric film 14 is stretched in the right-left direction, for example. The piezoelectric film 14 generates a negative charge when the piezoelectric film 14 is stretched in the front-rear direction, for example. The magnitude of an electric charge depends on an amount of deformation of the piezoelectric film 14 due to stretching or contraction. More precisely, the magnitude of the electric charge is proportional to a differential value of the amount of deformation of the piezoelectric film 14 due to stretching or contraction.

The upper electrode 15a is a signal electrode. The detection signal is output from the upper electrode 15a. As illustrated in FIG. 3, the upper electrode 15a is disposed on the fifth upper main surface US5 of the piezoelectric film 14. The lower electrode 15b is a ground electrode. The lower electrode 15b is connected to the ground. As illustrated in FIG. 3, the lower electrode 15b is disposed on the fifth lower main surface LS5 of the piezoelectric film 14.

As illustrated in FIG. 3, the substrate 16 is disposed on the upper electrode 15a. The substrate 16 holds the piezoelectric film 14, the upper electrode 15a, and the lower electrode 15b, and is deformed together with the piezoelectric film 14. The substrate 16 has a sheet shape. The substrate 16 has an upper main surface and a lower main surface. A length of the substrate 16 in the right-left direction is longer than a length of the substrate 16 in the front-rear direction. In the present embodiment, the substrate 16 has a rectangular shape having a long side extending in the right-left direction as viewed in the vertical direction. The long side of the substrate 16 is longer than the long side of the piezoelectric film 14, a long side of the upper electrode 15a, and a long side of the lower electrode 15b. A short side of the substrate 16 is longer than a short side of the piezoelectric film 14, a short side of the upper electrode 15a, and a short side of the lower electrode 15b. The piezoelectric film 14, the upper electrode 15a, and the lower electrode 15b are disposed in a region surrounded by the outer edge of the substrate 16 as viewed in the vertical direction. The material of the substrate 16 is, for example, polyurethane or PET. The substrate 16 may be formed of a flexible substrate or a printed wiring board. In a case where the substrate 16 is formed of a flexible substrate or a printed wiring board, the upper electrode 15a may be formed in the flexible substrate or the printed wiring board, and the piezoelectric film 14 may be fixed to the substrate 16 by the adhesive layer 18 described later.

The adhesive layer 18 fixes the piezoelectric film 14, the upper electrode 15a, and the lower electrode 15b to the substrate 16. More specifically, as illustrated in FIG. 3, the adhesive layer 18 is disposed on the lower main surface of the substrate 16. The adhesive layer 18 covers a part of the lower main surface of the substrate 16. As illustrated in FIG. 3, the adhesive layer 18 covers the entire upper main surface of the upper electrode 15a. The outer edge of the adhesive layer 18 is surrounded by the outer edge of the substrate 16 as viewed in the vertical direction. The adhesive layer 18 allows the upper electrode 15a and the substrate 16 to adhere to each other. As a result, the deformation of the substrate 16 is transmitted to the piezoelectric film 14. The material of the adhesive layer 18 is, for example, a double-sided tape, a thermosetting adhesive, or a thermoplastic adhesive.

As illustrated in FIG. 1, the adhesive member 8 fixes the sensor 6 to the first lower main surface LS1 of the operation panel 2. In the present specification, “the adhesive member 8 fixes the sensor 6 to the first lower main surface LS1 of the operation panel 2” means that the adhesive member 8 may directly fix the sensor 6 to the first lower main surface LS1 of the operation panel 2, or the adhesive member 8 may fix the sensor 6 to another member fixed to the first lower main surface LS1 of the operation panel 2. In the present embodiment, as illustrated in FIG. 2, the adhesive member 8 fixes the sensor 6 to the plate-shaped member 7. More specifically, the adhesive member 8 fixes the substrate 16 of the sensor 6 to the fourth lower main surface LS4 of the plate-shaped member 7.

In assembling of the electronic device 1, the sensor 6 is attached to the first lower main surface LS1 of the operation panel 2 or another member fixed to the first lower main surface LS1 of the operation panel 2 with the adhesive member 8 interposed therebetween. Therefore, it is desirable that the sensor 6 be easily attached to the first lower main surface LS1 of the operation panel 2 or another member fixed to the first lower main surface LS1 of the operation panel 2 by a small jig or the like without using large equipment such as thermocompression bonding equipment or coating equipment. In addition, the portable electronic terminal is required to be thinned. Therefore, it is desirable that the adhesive member 8 be a sheet-like member that facilitates management of the thickness in the vertical direction. Therefore, in the present embodiment, the adhesive member 8 is a double-sided tape. In addition, the adhesive member 8 desirably overlaps the entire fifth upper main surface US5 of the piezoelectric film 14 of the sensor 6 as viewed in the vertical direction. In the present embodiment, as illustrated in FIGS. 1 and 3, the shape of the adhesive member 8 is the same as the shape of the substrate 16 of the sensor 6 as viewed in the vertical direction. As illustrated in FIGS. 2 and 3, the adhesive member 8, the substrate 16 of the sensor 6, the adhesive layer 18 of the sensor 6, and the piezoelectric film 14 of the sensor 6 are arranged in this order on a straight line parallel to the vertical direction.

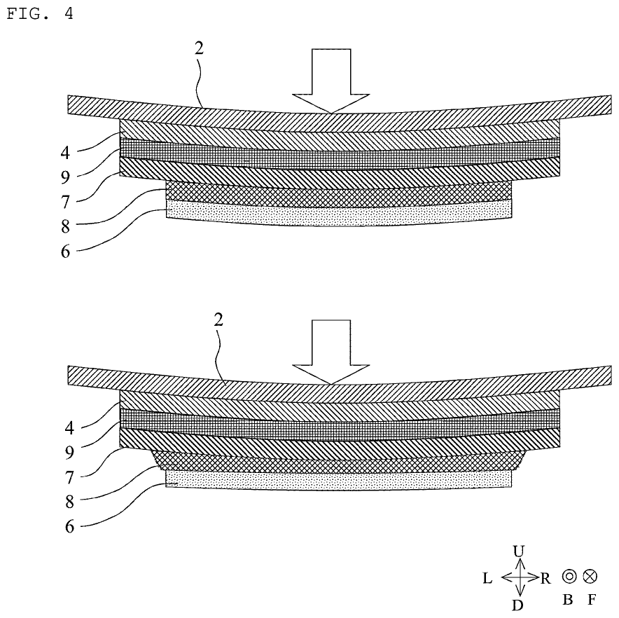

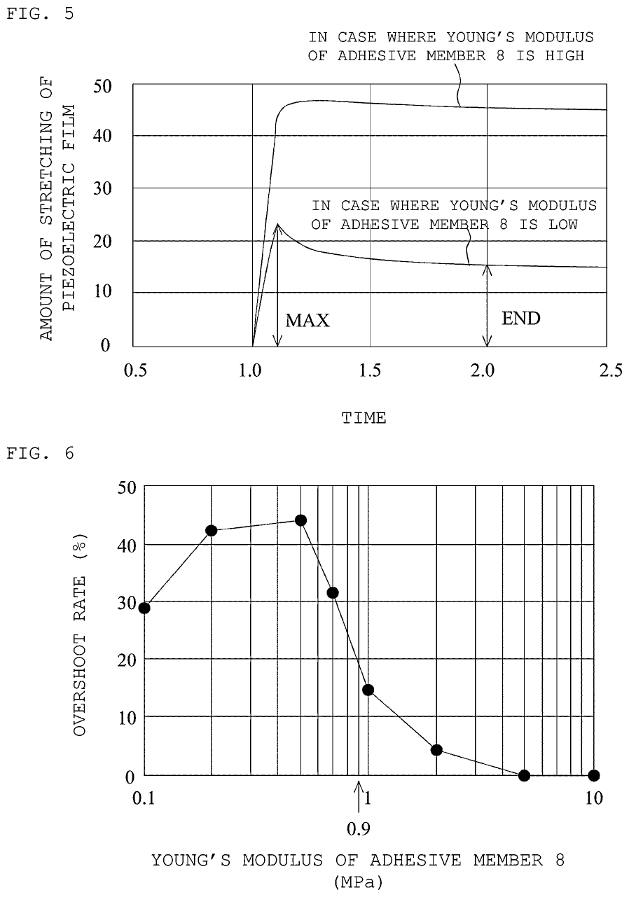

By the way, the electronic device 1 has a structure capable of accurately detecting the magnitude of a force with which the user presses the operation panel 2. This structure will be described below. FIG. 4 is a sectional view of the operation panel 2, the display panel 4, the buffer member 9, the plate-shaped member 7, the adhesive member 8, and the sensor 6. FIG. 5 is a graph illustrating a relationship between an amount of stretching of the piezoelectric film 14 and time. The horizontal axis represents time. The vertical axis represents the amount of stretching of the piezoelectric film 14.

In the electronic device 1, when the Young's modulus of the adhesive member 8 is low, overshoot occurs. The occurrence of such overshoot causes a decrease in the accuracy of detecting the magnitude of the force with which the user presses the operation panel 2. The overshoot will be described below.

As illustrated in the upper diagram of FIG. 4, when the user presses the operation panel 2 downward, the operation panel 2 becomes bent so as to protrude downward. At this time, the operation panel 2 extends in a direction orthogonal to the vertical direction. The direction orthogonal to the vertical direction is, for example, the front-rear direction or the right-left direction. The buffer member 9, the plate-shaped member 7, the adhesive member 8, and the sensor 6 are fixed to the first lower main surface LS1 of the operation panel 2. Therefore, as illustrated in FIG. 5, the buffer member 9, the plate-shaped member 7, the adhesive member 8, and the sensor 6 extend in a direction orthogonal to the vertical direction. That is, the piezoelectric film 14 extends in a direction orthogonal to the vertical direction. As a result, the detection signal output from the sensor 6 rises.

However, when the Young's modulus of the adhesive member 8 is low, the adhesive member 8 tends to return to a planar shape by stress relaxation as illustrated in the lower diagram of FIG. 4. Therefore, the amount of stretching of the piezoelectric film 14 decreases as illustrated in FIG. 5. That is, overshoot occurs. On the other hand, when the Young's modulus of the adhesive member 8 is high, such overshoot hardly occurs. The amount of a decrease in the amount of stretching of the piezoelectric film 14 due to stress relaxation is proportional to the thickness of the adhesive member 8 in the vertical direction. That is, in a case where the Young's modulus of the adhesive member 8 is the same condition, such overshoot is less likely to occur when the thickness of the adhesive member 8 in the vertical direction is small.

Therefore, the inventor of the present application performed computer simulation in order to suppress the occurrence of overshoot. Specifically, the overshoot rate was examined by setting the thickness of the adhesive member 8 to 100 μm and changing the Young's modulus in a range of 0.1 MPa to 10 MPa. As illustrated in FIG. 5, the overshoot rate is a value obtained by multiplying a value obtained by dividing a difference between the maximum value MAX of the amount of stretching of the sensor 6 and the last value END of the amount of stretching of the sensor 6 by the maximum value MAX of the amount of stretching of the sensor 6 by 100. The material of the plate-shaped member 7 is SUS. FIG. 6 is a graph illustrating a relationship between the Young's modulus of the adhesive member 8 and the overshoot rate. The horizontal axis represents the Young's modulus of the adhesive member 8. The vertical axis represents the overshoot rate.

As illustrated in FIG. 6, it can be seen that when the Young's modulus of the adhesive member 8 is 0.9 MPa or more, the overshoot rate is 20% or less. Therefore, the adhesive member 8 may have a Young's modulus of 0.9 MPa or more. As illustrated in FIG. 6, it has been confirmed that the overshoot rate is almost 0% when the Young's modulus of the adhesive member 8 is 5 MPa, and the overshoot rate is sufficiently low when the Young's modulus of the adhesive member 8 is 10 MPa. Therefore, the adhesive member 8 may have a Young's modulus of 10 MPa or less, and the Young's modulus of the adhesive member 8 is more preferably 5 MPa or less. As a result, the electronic device 1 can accurately detect the magnitude of a force with which the user presses the operation panel 2.

### Other Embodiments

The electronic device 1 according to the present disclosure is not limited to the electronic device 1, and can be modified within the scope of the gist thereof.

The piezoelectric film 14 may be a PVDF (polyvinylidene fluoride) film. Further, the piezoelectric film 14 may be piezoelectric ceramic. Furthermore, the sensor 6 may include a strain sensor.

Note that, in the electronic device 1, the housing 3, the display panel 4, the adhesive member 5, the plate-shaped member 7, and the buffer member 9 are not essential components.

Note that the adhesive member 5 may not have waterproofness.

Note that the two sides extending in the front-rear direction may be short sides, and the two sides extending in the right-left direction may be long sides.

Note that the sensor 6 may be disposed at a position other than the center of the plate-shaped member 7 in the front-rear direction as viewed in the vertical direction.

The operation panel 2 may not be a transparent plate. The operation panel 2 may be, for example, a resin plate or a printed wiring board. Further, the operation panel 2 may include a touch pad instead of the touch panel. In this case, the display panel 4 and the plate-shaped member 7 are unnecessary.

Note that the sensor 6 may not have the longitudinal direction extending in the right-left direction. The sensor 6 may have a longitudinal direction extending in the front-rear direction.

The display panel 4 may not include the touch panel.

The adhesive member 8 is not limited to the double-sided tape, and may be a thermosetting adhesive or a thermoplastic adhesive.

The shape of the adhesive member 8 may not be the same as the shape of the substrate 16 of the sensor 6 as viewed in the vertical direction.

In a case where the thickness of the adhesive member 8 in the vertical direction is 40 μm or more, the adhesive member 8 can more firmly fix the sensor 6 to the operation panel 2. Therefore, the thickness of the adhesive member 8 in the vertical direction may be 40 μm to 100 μm.

The computer simulation performed in the electronic device 1 is not limited to the adhesive member 8, and can also be applied to an adhesive member or an adhesive layer overlapping the plate-shaped member 7 and the piezoelectric film 14 as viewed in the vertical direction and present between the plate-shaped member 7 and the piezoelectric film 14. That is, the computer simulation performed in the electronic device 1 can also be applied to the adhesive layer 18. Therefore, the adhesive layer 18 may have a Young's modulus of 0.9 MPa to 10 MPa.

In a case where the thickness of the adhesive layer 18 in the vertical direction is 10 μm or more, the adhesive layer 18 can more firmly fix the piezoelectric film 14 to the substrate 16. Therefore, the thickness of the adhesive layer 18 in the vertical direction may be 10 μm to 100 μm.

Note that the buffer member 9 is desirably soft in order to absorb an impact applied to the portable electronic terminal. Specifically, the buffer member 9 may have a Young's modulus of 300 kPa or less.

### DESCRIPTION OF REFERENCE SYMBOLS

1: Electronic device
2: Operation panel
3: Housing
4: Display panel
5: Adhesive member
6: Sensor
7: Plate-shaped member
8: Adhesive member
9: Buffer member
14: Piezoelectric film
15a: Upper electrode
15b: Lower electrode
16: Substrate
18: Adhesive layer

1. An electronic device comprising:
an operation panel having a first upper main surface and a first lower main surface that are arranged in a vertical direction such that a part of a body of a user or an operation member is capable of contacting the first upper main surface;
a sensor fixed to the first lower main surface and constructed to detect deformation of the operation panel; and
an adhesive member fixing the sensor to the first lower main surface,
wherein the adhesive member has a Young's modulus of 0.9 MPa to 10 MPa.

2. The electronic device according to claim 1, further comprising a display panel that has a second upper main surface and a second lower main surface that are arranged in the vertical direction, and is fixed to the first lower main surface of the operation panel.

3. The electronic device according to claim 1, wherein a thickness of the adhesive member in the vertical direction is 40 μm to 100 μm.

4. The electronic device according to claim 3, further comprising a display panel that has a second upper main surface and a second lower main surface that are arranged in the vertical direction, and is fixed to the first lower main surface of the operation panel.

5. The electronic device according to claim 1, further comprising:
a buffer member that has a third upper main surface and a third lower main surface that are arranged in the vertical direction, and is fixed to the first lower main surface of the operation panel; and
a plate-shaped member that has a fourth upper main surface and a fourth lower main surface that are arranged in the vertical direction, and is fixed to the first lower main surface of the operation panel.

6. The electronic device according to claim 1, wherein the operation panel has a rectangular shape having two long sides extending in a front-rear direction and two short sides extending in a right-left direction as viewed in the vertical direction.

7. The electronic device according to claim 6, wherein the sensor is located at a center of the operation panel in the front-rear direction as viewed in the vertical direction.

8. The electronic device according to claim 1, wherein the sensor includes a piezoelectric film having a fifth upper main surface and a fifth lower main surface that are arranged in the vertical direction.

9. The electronic device according to claim 8, wherein the piezoelectric film is constructed such that a polarity of an electric charge generated by the piezoelectric film when the piezoelectric film is stretched in a right-left direction is different from a polarity of an electric charge generated by the piezoelectric film when the piezoelectric film is stretched in a front-rear direction.

10. The electronic device according to claim 8, wherein
the sensor includes a substrate having an upper main surface and a lower main surface that are arranged in the vertical direction, and an adhesive layer fixing the piezoelectric film to the substrate, and
the adhesive member, the substrate, the adhesive layer, and the piezoelectric film are arranged in this order on a straight line parallel to the vertical direction.

11. The electronic device according to claim 10, wherein a thickness of the adhesive layer in the vertical direction is 10 μm to 100 μm.

12. The electronic device according to claim 11, wherein a thickness of the adhesive member in the vertical direction is 40 μm to 100 μm.

13. The electronic device according to claim 10, wherein the adhesive layer has a Young's modulus of 0.9 MPa to 10 MPa.

14. The electronic device according to claim 12, wherein a thickness of the adhesive layer in the vertical direction is 10 μm to 100 μm.

15. The electronic device according to claim 14, wherein a thickness of the adhesive member in the vertical direction is 40 μm to 100 μm.

16. The electronic device according to claim 1, wherein the sensor has a longitudinal direction extending in a right-left direction.

17. The electronic device according to claim 1, wherein the sensor includes a strain sensor.

18. The electronic device according to claim 1, wherein a material of the operation panel is glass.
